(19) United States
(12) Patent Application Publication
(10) Pub. No.: US 2008/0141509 A1
(43) Pub. Date: Jun. 19, 2008

(54) SUBSTRATE PROCESSING SYSTEM, SUBSTRATE PROCESSING METHOD, AND STORAGE MEDIUM

(75) Inventor: Eiichi NISHIMURA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/950,832

(22) Filed: Dec. 5, 2007

Related U.S. Application Data
(60) Provisional application No. 60/891,911, filed on Feb. 27, 2007.

(30) Foreign Application Priority Data
Dec. 19, 2006 (JP) 2006-341282

(51) Int. Cl. H01L 21/67; G06F 17/50

(52) U.S. Cl. 29/25.01; 716/1

(57) ABSTRACT

A substrate processing system that can reliably prevent a rear surface of a substrate from getting scratched without bringing about a decrease in the throughput. A printing module connected to a loader module prints a protective film on the rear surface of the substrate before the substrate is subjected to plasma etching processing. A cleaning module connected to the loader module removes the protective film from the rear surface of the substrate after the substrate has been subjected to the plasma etching processing.

### BACKGROUND OF THE INVENTION

1. Field of the Invention

The present invention relates to a substrate processing system, a substrate processing method, and a storage medium, and in particular to a substrate processing system having an etching apparatus that electrostatically attracts and holds a substrate.

2. Description of the Related Art

To form a wiring trench or a via hole with a desired pattern on a surface of a wafer as a substrate using plasma, a photoresist apparatus that forms a resist with a desired pattern on the surface of the wafer, an etching apparatus that subjects the surface of the wafer to etching processing such as RIE (Reactive Ion Etching), and a cleaning apparatus that removes the resist are used. Here, the photoresist apparatus has a coater that coats photosensitive resin on a surface of a wafer, a stepper that exposes the photosensitive resin to light, and a developer that removes the photosensitive resin which has not yet hardened from the surface of the wafer. The etching apparatus has a chamber in which the wafer is housed and plasma is produced, and an electrostatic chuck that is disposed in the chamber and electrostatically attracts and holds the wafer while the wafer is subjected to the etching processing (see, for example, Japanese Laid-Open Patent Publication (Kokai) No. 2005-347620).

The stepper irradiates a ray of ultraviolet light or the like with a desired pattern onto the photosensitive resin on the surface of the wafer. In recent years, due to miniaturization of the desired pattern, a ray of ultraviolet light with a short wavelength, for example, a wavelength of 193 nm has been used. When the wavelength is short, the depth of focus is also small, and hence the allowable flatness and inclination of the wafer are small. Moreover, in the stepper, a plurality of pin-shaped projections support the rear surface of the wafer, and hence scratches, foreign matter, etc. on the rear surface of the wafer greatly affect the flatness and inclination of the wafer.

Meanwhile, to realize complicated wiring structure and electrode structure of a wafer for a semiconductor device, the wafer is repeatedly subjected to etching by a substrate processing system, and each time etching is carried out, the wafer is electrostatically attracted to and held on the electrostatic chuck. A surface of the electrostatic chuck is coated with yttria (Y₂O₃), and hence a rear surface of the attracted wafer made of silicon (Si) may get scratched. Also, the surface of the electrostatic chuck may get scratched due to contact with the attracted wafer. Then, foreign matter produced due to the scratched surface of the electrostatic chuck may be transferred and attached to the rear surface of the wafer.

Conventionally, foreign matter attached to a rear surface of a wafer can be removed by wet cleaning using a cleaning solution or the like, but there is unknown a method of effectively removing scratches on the rear surface of the wafer. As a result, there is a possibility that the allowable flatness and inclination of the wafer will not be maintained due to scratches on the rear surface of the wafer as described above. Therefore, it is necessary to prevent the rear surface of the wafer from getting scratched when the wafer is attracted to the electrostatic chuck.

For this reason, the present inventors have proposed a substrate processing system that forms a protective film on a rear surface of a wafer prior to etching processing by carrying out deposition processing, i.e. CVD processing, or coating processing, i.e. spin coat processing, and brings the protective film formed on the rear surface of the wafer into contact with a surface of an electrostatic chuck when the wafer is attracted to the electrostatic chuck, so that the rear surface of the wafer can be prevented from getting scratched.

However, in the above described CVD processing or spin coat processing, a protective film is thinly formed on a rear surface of a wafer, and when the wafer is repeatedly electrostatically attracted to and held on the electrostatic chuck, the protective film thinly formed on the rear surface of the wafer may be broken, and as a result, the rear surface of the wafer may get scratched.

Moreover, the above described wet cleaning and CVD processing or spin coat processing has brought about a significant decrease in the throughput of the substrate processing system.

### SUMMARY OF THE INVENTION

The present invention provides a substrate processing system, a substrate processing method, and a storage medium, which can reliably prevent a rear surface of a substrate from getting scratched without bringing about a decrease in the throughput.

Accordingly, in a first aspect of the present invention, there is provided a substrate processing system having an etching apparatus that subjects a substrate to plasma etching processing, a vacuum substrate transfer apparatus having the etching apparatus connected thereto, and an atmospheric substrate transfer apparatus connected to the vacuum substrate transfer apparatus, wherein the etching apparatus has a mounting stage that electrostatically attracts and holds the substrate, and the mounting stage contacts a rear surface of the substrate, the substrate processing system comprising a protective film printing apparatus that is connected to the atmospheric substrate transfer apparatus and prints a protective film on the rear surface of the substrate before the substrate is subjected to the plasma etching processing, and a protective film removing apparatus that is connected to the atmospheric substrate transfer apparatus and removes the protective film from the rear surface of the substrate after the substrate has been subjected to the plasma etching processing.

According to the first aspect of the present invention, because a protective film is printed on a rear surface of a substrate before the substrate is subjected to the plasma etching processing, and the protective film is removed from the rear surface of the substrate after the substrate has been subjected to the plasma etching processing, the mounting stage contacts the protective film thickly printed on the rear surface of the substrate. Therefore, even when the substrate is repeatedly attracted to and held on the mounting stage, the rear surface of the substrate can be reliably prevented from getting scratched.

The present invention can provide a substrate processing system, wherein the protective film printing apparatus prints the protective film by carrying out a screen printing process.

According to the first aspect of the present invention, because a protective film is printed by carrying out the screen printing process, the protective film can be reliably thickly printed. Further, because the screen printing process is carried out at normal pressure, the throughput of the substrate processing system is not significantly decreased.

The present invention can provide a substrate processing system, wherein the protective film printing apparatus prints the protective film by attaching a predetermined film.

According to the first aspect of the present invention, because a protective film is printed by attaching a predetermined film, the protective film can be reliably thickly printed. Further, because the attachment of the predetermined film is carried out at normal pressure, the throughput of the substrate processing system is not significantly decreased.

The present invention can provide a substrate processing system, wherein the protective film removing apparatus removes the protective film by carrying out a normal pressure plasma ashing process.

According to the first aspect of the present invention, a protective film is removed by carrying out the normal pressure plasma ashing process, the protective film can be reliably removed. Further, because the normal pressure plasma ashing process is carried out at normal pressure, the throughput of the substrate processing system is not significantly decreased.

The present invention can provide a substrate processing system, wherein the protective film removing apparatus removes the protective film by carrying out a superheated steam jetting process.

According to the first aspect of the present invention, a protective film is removed by carrying out the superheated steam jetting process, the protective film can be reliably removed. Further, because the superheated steam jetting process is carried out at normal pressure, the throughput of the substrate processing system is not significantly decreased.

The present invention can provide a substrate processing system, wherein the protective film is made of resin.

According to the first aspect of the present invention, because a protective film is made of resin, the protective film can be thickly printed with ease.

The present invention can provide a substrate processing system, wherein the protective film is made of one selected from the following: silica, organic polymer of fluorine-free aromatic hydrocarbon, polyimide, and resist.

According to the first aspect of the present invention, because a protective film is made of one selected from the following: silica, organic polymer of fluorine-free aromatic hydrocarbon, polyimide, and resist, the protective film can be thickly printed with ease.

The present invention can provide a substrate processing system, wherein in an upper portion of the mounting stage, a base material of the mounting stage is exposed.

According to the first aspect of the present invention, in the upper portion of the mounting stage, the base material of the mounting stage is exposed. As a result, in a case where a substrate having a rear surface with a protective film thickly printed thereon is mounted on the upper surface of the mounting stage, the substrate is mounted on the upper surface of the mounting stage whose base material is exposed. Therefore, the substrate can be attracted and held without disposing an electrostatic chuck in the upper portion of the mounting stage, and hence the construction of the mounting stage can be simplified.

The present invention can provide a substrate processing system, wherein the protective film removing apparatus holds the substrate without contacting the substrate.

According to the first aspect of the present invention, the protective film removing apparatus holds the substrate without contacting the substrate when a protective film is removed, the protective film can be reliably removed, and a decrease in the throughput of the substrate processing system can be reliably prevented.

Accordingly, in a second aspect of the present invention, there is provided a substrate processing method in a substrate processing system having at least an etching apparatus that subjects a substrate to plasma etching processing, wherein the etching apparatus has a mounting stage that electrostatically attracts and holds the substrate, and the mounting stage contacts a rear surface of the substrate, the substrate processing method comprising a printing step of printing a protective film on the rear surface of the substrate, an etching step of subjecting a front surface of the substrate to the plasma etching processing, and a removing step of removing the protective film.

The present invention can provide a substrate processing method, wherein in the printing step, the protective film is printed by carrying out a screen printing process.

The present invention can provide a substrate processing method, wherein in the printing step, the protective film is printed by attaching a predetermined film.

The present invention can provide a substrate processing method, wherein in the removing step, the protective film is removed by carrying out a normal pressure plasma ashing process.

The present invention can provide a substrate processing method, wherein in the removing step, the protective film is removed by carrying out a superheated steam jetting process.

The present invention can provide a substrate processing method, wherein the protective film is made of resin.

The present invention can provide a substrate processing method, wherein the protective film is made of one selected from the following: silica, organic polymer of fluorine-free aromatic hydrocarbon, polyimide, and resist.

The present invention can provide a substrate processing method, wherein in the removing step, the substrate is held without contact.

Accordingly, in a third aspect of the present invention, there is provided a computer-readable storage medium storing a program for causing a computer to execute a substrate processing method in a substrate processing system having at least an etching apparatus that subjects a substrate to plasma etching processing, wherein the etching apparatus has a mounting stage that electrostatically attracts and holds the substrate, and the mounting stage contacts a rear surface of the substrate, the substrate processing method comprising a printing step of printing a protective film on the rear surface of the substrate, an etching step of subjecting a front surface of the substrate to the plasma etching processing, and a removing step of removing the protective film.

The features, and advantages of the invention will become more apparent from the following detailed description taken in conjunction with the accompanying drawings.

### BRIEF DESCRIPTION OF THE DRAWINGS

FIG. 1 is a plan view schematically showing the construction of a substrate processing system according to an embodiment of the present invention;

FIG. 2 is sectional view schematically showing the construction of a printing module appearing in FIG. 1;

FIG. 3 is sectional view schematically showing the construction of a process module appearing in FIG. 1;

FIG. 4 is sectional view schematically showing the construction of a cleaning module appearing in FIG. 1; and

FIG. 5 is a sectional view schematically showing a variation of the cleaning module that removes a protective film from a rear surface of a wafer.

### DETAILED DESCRIPTION OF THE PREFERRED EMBODIMENTS

The present invention will now be described in detail below with reference to the accompanying drawings showing a preferred embodiment thereof.

First, a description will be given of a substrate processing system according to an embodiment of the present invention.

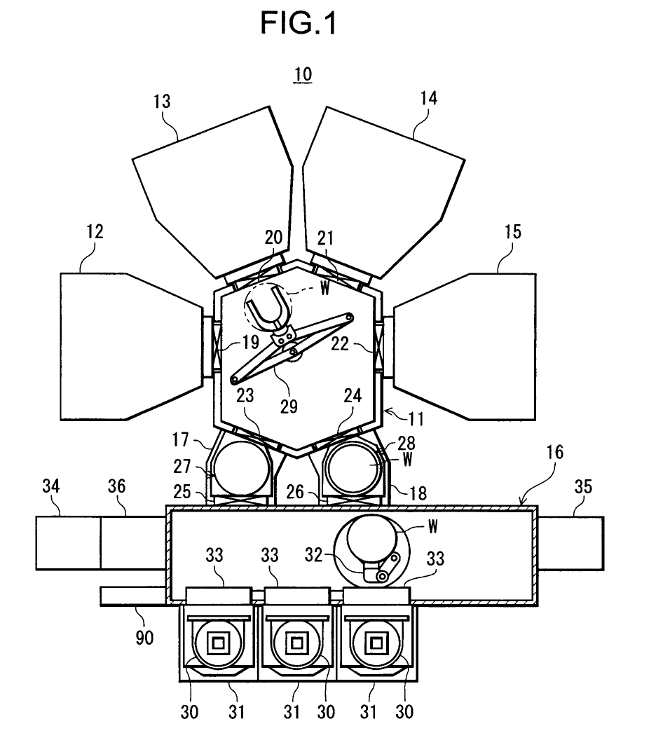

FIG. 1 is a plan view schematically showing the construction of a substrate processing system according to the embodiment.

As shown in FIG. 1, the substrate processing system 10 is comprised of a transfer module 11 (vacuum substrate transfer apparatus) that is hexagonal in plan view, four process modules 12 to 15 that are arranged in a radial pattern around the transfer module 11 and subject wafers for semiconductor devices (hereinafter referred to merely as “wafers”) W (substrates) to predetermined processing, a loader module 16 (atmospheric substrate transfer apparatus) as a common rectangular transfer chamber, two load-lock modules 17 and 18 that are disposed between the transfer module 11 and the loader module 16 and connect the transfer module 11 and the loader module 16 together.

The interiors of the transfer module 11 and the process modules 12 to 15 are maintained under vacuum, and the transfer module 11 and the process modules 12 to 15 are connected together via respective vacuum gate valves 19 to 22.

In the substrate processing system 10, the interior of the loader module 16 is maintained at atmospheric pressure, while the interior of the transfer module 11 is maintained under vacuum. Thus, the load-lock modules 17 and 18 have vacuum gate valves 23 and 24, respectively, at joints to the transfer module 11, and have atmospheric door valves 25 and 26, respectively, at joints to the loader module 16, so that the load-lock modules 17 and 18 act as vacuum auxiliary transfer chambers of which internal pressures are controllable. The load-lock modules 17 and 18 also have wafer mounting stages 27 and 28, respectively, on which wafers W transferred between the loader module 16 and the transfer module 11 are temporarily mounted.

The transfer module 11 has therein a transfer arm 29 of a frog leg type which is constructed such as to be able to bend, extend and whirl about a pivot thereof, and the transfer arm 29 transfers wafers W between the process modules 12 to 15 and the load-lock modules 17 and 18.

To the loader module 16 are connected three FOUP (Front Opening Unified Pod) mounting stages 31 on which respective FOUPs 30 as containers each housing 25 wafers W are mounted, a printing module 34 that prints a protective film, described later, on a rear surface of a wafer W via a wafer inverting module 36 that inverts the wafer W, and a cleaning module 35 that removes the protective film from the rear surface of the wafer W, as well as the above described load-lock modules 17 and 18.

The load-lock modules 17 and 18 are connected to a side wall of the loader module 16 in the longitudinal direction thereof and disposed such as to face the three FOUP mounting stages 31 across the loader module 16. The printing module 34 is disposed at one end of the loader module 16 as viewed in the longitudinal direction thereof, and the cleaning module 35 is disposed at the other end of the loader module 16 as viewed in the longitudinal direction thereof.

The loader module 16 has therein a transfer arm mechanism 32 of a SCARA dual arm type for transferring wafers W, and three load ports 33 through which wafers W are transferred and which are disposed on a side wall of the loader module 16 such as to correspond to the respective FOUP mounting stages 31. The transfer arm mechanism 32 removes each wafer W from the FOUPs 30 mounted on the FOUP mounting stages 31 via the load ports 33 and transfers the removed wafer W into the printing module 34 and the cleaning module 35 via the load-lock module 17 and 18 and the wafer inverting module 36.

In the substrate processing system 10, the printing module 34 (protective film printing apparatus) prints a protective film, described later, on a rear surface of a wafer W, the process module 13 (etching apparatus) subjects the wafer W to the RIE processing, and the cleaning module 35 (protective film removing apparatus) removes the protective film printed on the rear surface of the wafer W. In the substrate processing system 10, the wafer W is sequentially transferred to the printing module 34, the process module 13, and the cleaning module 35 in this order. It should be noted that the wafer W is inverted by the wafer inverting module 36 before being transferred into the printing module 34.

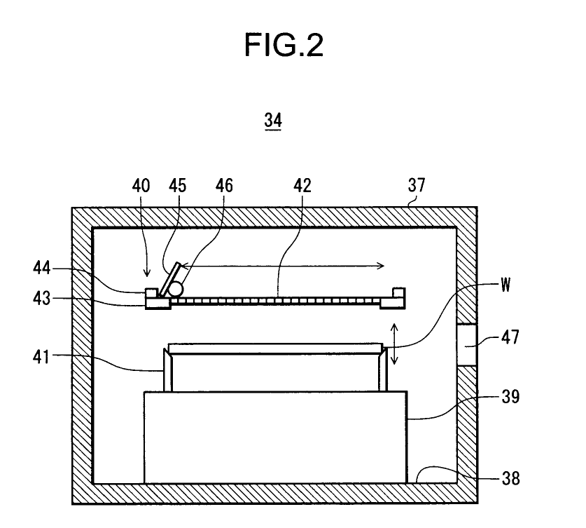

FIG. 2 is sectional view schematically showing the construction of the printing module 34 appearing in FIG. 1.

As shown in FIG. 2, the printing module 34 has a box-shaped chamber 37 in which a wafer W is housed, a mounting stage 39 that is disposed in a bottom portion 38 of the chamber 37, and a screen printing unit 40 that is disposed at a predetermined distance from the mounting stage 39 such as to face the mounting stage 39.

The mounting stage 39 is a cylindrical projection, and a plurality of lift pins 41 are disposed on an upper surface of the mounting stage 39. The top of each lift pin 41 has an oblique surface, and the lift pins 41 contact a peripheral portion of a surface of a wafer W transferred into the chamber 37 and support the wafer W. The lift pins 41 are able to move the wafer W up and down (vertically) as viewed in the drawing. When a wafer W is to be transferred into and out from the chamber 37, the lift pins 41 move the wafer W so that the wafer W can be positioned at the height of a transfer port 47 for the wafers W, which is provided in a side wall of the chamber 37.

The screen printing unit 40 has a screen film 43 on which a print film 42 having the same shape as the rear surface of the wafer W is formed, a frame 44 to which the screen film 43 is attached in a stretched manner, and a spatula-shaped squeegee 45 disposed above the screen film 43.

The printing module 34 carries out a screen printing process so as to print a protective film made of resin on the rear surface of the wafer W. Specifically, first, the lift pins 41 move the wafer W so that the rear surface of the wafer W can be positioned at a predetermined height below the screen printing unit 40, and then an insulating resin 46 is placed on the screen film 43. The squeegee 45 is moved in the horizontal direction as viewed in the drawing while the resin 46 is being pressurized against the screen film 41, in particular, against the print film 42 by the squeegee 45, so that a protective film made of the resin 46 is printed on the rear surface of the wafer W.

The printing module 34 prints a protective film with a thickness of 30 to 50 μm on the rear surface of the wafer W. It should be noted that the resin 46 to be printed has only to be, for example, polyimide. Also, the protective film to be printed is not limited to being a protective film made of resin, but may be a protective film made of silica (SiO₂) or a resist, or a protective film made of an organic polymer comprised of fluorine-free aromatic hydrocarbon, i.e. a SILK (registered trademark).

Although in the present embodiment, the protective film is printed on the rear surface of the wafer W by carrying out the screen printing process, the protective film may be printed on the rear surface of the wafer W by carrying out a film attaching process in which a resin film (predetermined film) produced in advance such as to suit the shape of the rear surface of the wafer W is attached to the rear surface of the wafer W.

The wafer W having the rear surface with the protective film formed thereon by the printing module 34 is transferred out from the chamber 37, then inverted by the wafer inverting module 36, and further transferred by the loader module 16.

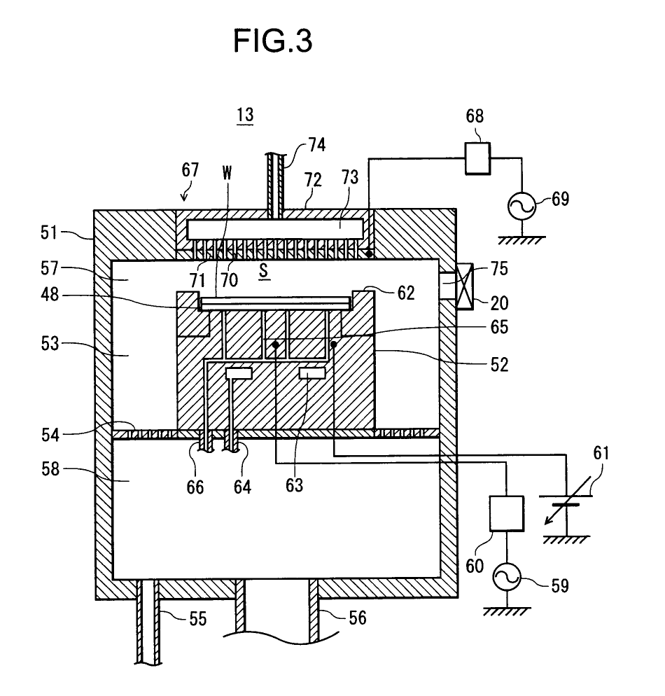

FIG. 3 is a sectional view schematically showing the construction of the process module 13 appearing in FIG. 1.

As shown in FIG. 3, the process module 13 has a chamber 51 in which is housed a wafer W having a rear surface with a protective film 48 formed thereon by the above described printing module 34, and a cylindrical susceptor 52 as a mounting stage on which the wafer W is mounted is disposed in the chamber 51.

In the process module 13, a side exhaust path 53 that acts as a flow path through which gas above the susceptor 52 is discharged to the outside of the chamber 51 is formed between the inside wall of the chamber 51 and the side face of the susceptor 52. An exhaust plate 54 is disposed part way along the exhaust path 53.

The exhaust plate 54 is a plate-shaped member having a large number of holes therein and acts as a partition plate that partitions the chamber 51 into an upper part and a lower part thereof. In the upper part 57 of the chamber 51 partitioned by the exhaust plate 54, the susceptor 52 on which the wafer W is mounted and other components are disposed, and plasma is produced. The upper part of the chamber 51 will be hereinafter referred to as the “reactive chamber.” Moreover, a roughing exhaust pipe 55 and a main exhaust pipe 56 through which gas in the chamber 51 is discharged are provided opening out from the lower part (hereinafter referred to as the “exhaust chamber (manifold)”) 58 of the chamber 51. The roughing exhaust pipe 55 has a DP (dry pump) (not shown) connected thereto, and the main exhaust pipe 56 has a TMP (turbo-molecular pump) (not shown) connected thereto. The exhaust plate 54 captures or reflects ions and radicals, which are produced in a processing space S, described later, of the reactive chamber 57, so as to prevent the ions and the radicals from leaking into the manifold 58.

The roughing exhaust pipe 55, the main exhaust pipe 56, the DP, the TMP, and so on constitute an exhausting apparatus, which discharges gas in the reactive chamber 57 to the outside of the chamber 51 via the manifold 58. Specifically, the roughing exhaust pipe 55 reduces the pressure in the chamber 51 from atmospheric pressure down to a low vacuum state, and the main exhaust pipe 56 is operated in collaboration with the roughing exhaust pipe 55 to reduce the pressure in the chamber 51 from atmospheric pressure down to a high vacuum state (e.g. a pressure of not more than 133 Pa (1 Torr)), which is at a lower pressure than the low vacuum state.

A lower radio frequency power source 59 is connected to the susceptor 52 via a matcher 60. The lower radio frequency power source 59 supplies radio frequency electrical power of a predetermined frequency to the susceptor 52. The susceptor 52 thus acts as a lower electrode. The matcher 60 reduces reflection of the radio frequency electrical power from the susceptor 52 so as to maximize the efficiency of the supply of the radio frequency electrical power into the susceptor 52.

In general, a disk-shaped electrostatic chuck made of an insulating member, such as yttria, alumina (Al₂O₃), or silica, having therein an electrode plate to which a DC power source is electrically connected is provided in an upper portion of the susceptor 52. When a wafer W is mounted on the susceptor 52, the wafer W is disposed on the electrostatic chuck. Upon a negative DC voltage being applied to the electrode plate, a potential difference arises between the electrode plate and the rear surface of the wafer W, and hence the wafer W is attracted to and held on an upper surface of the electrostatic chuck through a Coulomb force or a Johnsen-Rahbek force due to the potential difference. On the other hand, in the present embodiment, the base material of the susceptor 52, such as aluminum, is exposed in the upper portion of the susceptor 52.

In the present embodiment, because the protective film 48 made of an insulating resin with a thickness of 30 to 50 μm is printed on the rear surface of the wafer W, the wafer W can be attracted to and held on the upper surface of the susceptor 52 in a state with the base material of the susceptor 52 being exposed without disposing the above-mentioned electrostatic chuck in the upper portion of the susceptor 52. Specifically, a DC power source 61 is electrically connected to the susceptor 52. Upon a negative DC voltage being applied to the susceptor 52, a positive potential is produced at a boundary between the wafer W and the protective film 48, and a negative potential is produced on a front surface of the wafer W. A potential difference thus arises between the upper surface of the susceptor 52 and the boundary between the wafer W and the protective film 48, and hence the wafer W is attracted to and held on the upper surface of the susceptor 52 through a Coulomb force or a Johnsen-Rahbek force due to the potential difference. It should be noted that in the present embodiment, the electrostatic chuck may be disposed in the upper portion of the susceptor 52.

An annular focus ring 62 is provided on an upper portion of the susceptor 52 so as to surround the wafer W attracted to and held on the upper surface of the susceptor 52. The focus ring 62 is exposed to the processing space S and focuses plasma in the processing space S toward the front surface of the wafer W, thus improving the efficiency of the RIE processing.

An annular coolant chamber 63 that extends, for example, in a circumferential direction of the susceptor 52 is provided inside the susceptor 52. A coolant, for example cooling water or a Galden (registered trademark) fluid, at a predetermined temperature is circulated through the coolant chamber 63 via coolant piping 64 from a chiller unit (not shown). The processing temperature of the wafer W attracted to and held on the upper surface of the susceptor 52 is controlled through the temperature of the coolant.

A plurality of heat transfer gas supply holes 65 are provided in a portion of the upper surface of the susceptor 52 on which the wafer W is attracted and held (hereinafter referred to as the “attracting surface”). The heat transfer gas supply holes 65 are connected to a heat transfer gas supply unit (not shown) via a heat transfer gas supply line 66. The heat transfer gas supply unit supplies helium gas as a heat transfer gas via the heat transfer gas supply holes 65 into a gap between the attracting surface of the susceptor 52 and the rear surface of the wafer W. The helium gas supplied into the gap between the attracting surface of the susceptor 52 and the rear surface of the wafer W transfers heat of the wafer W to the susceptor 52.

A plurality of pusher pins (not shown) are provided in the attracting surface of the susceptor 52 as lifting pins that can be made to project out from the attracting surface of the susceptor 52. The pusher pins are connected to a motor (not shown) by a ball screw (not shown) and can be made to project out from the attracting surface of the susceptor 52 through rotational motion of the motor, which is converted into linear motion by the ball screw. The pusher pins are housed inside the susceptor 52 when a wafer W is being attracted to and held on the attracting surface of the susceptor 52 so that the wafer W can be subjected to the RIE processing, and are made to project out from the upper surface of the susceptor 52 so as to lift the wafer W up away from the susceptor 52 when the wafer W is to be transferred out from the chamber 51 after having been subjected to the RIE processing.

A gas introducing shower head 67 is disposed in a ceiling portion of the chamber 51 (reactive chamber 57) so as to face the susceptor 52. An upper radio frequency power source 69 is connected to the gas introducing shower head 67 via a matcher 68, and the upper radio frequency power source 69 supplies radio frequency electrical power of a predetermined frequency into the gas introducing shower head 67. The gas introducing shower head 67 thus acts as an upper electrode. It should be noted that the matcher 68 has a similar function to the matcher 60.

The gas introducing shower head 67 has a ceiling electrode plate 71 having a number of gas holes 70 therein, and an electrode support 72 that detachably supports the ceiling electrode plate 71. A buffer chamber 73 is provided inside the electrode support 72, and a processing gas introducing pipe 74 is connected to the buffer chamber 73. A processing gas supplied from the processing gas introducing pipe 74 into the buffer chamber 73 is supplied by the gas introducing shower head 67 into the chamber 51 (reactive chamber 57) via the gas holes 70.

A transfer port 75 for the wafers W is provided in a side wall of the chamber 51 in a position at the height of a wafer W that has been lifted up from the susceptor 52 by the pusher pins. The vacuum gate valve 20 for opening and closing the transfer port 75 is provided in the transfer port 75.

In the chamber 51 of the process module 13, radio frequency electrical power is supplied into the susceptor 52 and the gas introducing shower head 67, and thus the radio frequency electrical power is applied to the processing space S between the susceptor 52 and the gas introducing shower head 67 as described above, whereby the processing gas supplied into the processing space S from the gas introducing shower head 67 is turned into high-density plasma, so that ions and radicals are produced. The wafer W is subjected to the RIE processing by the ions and radicals.

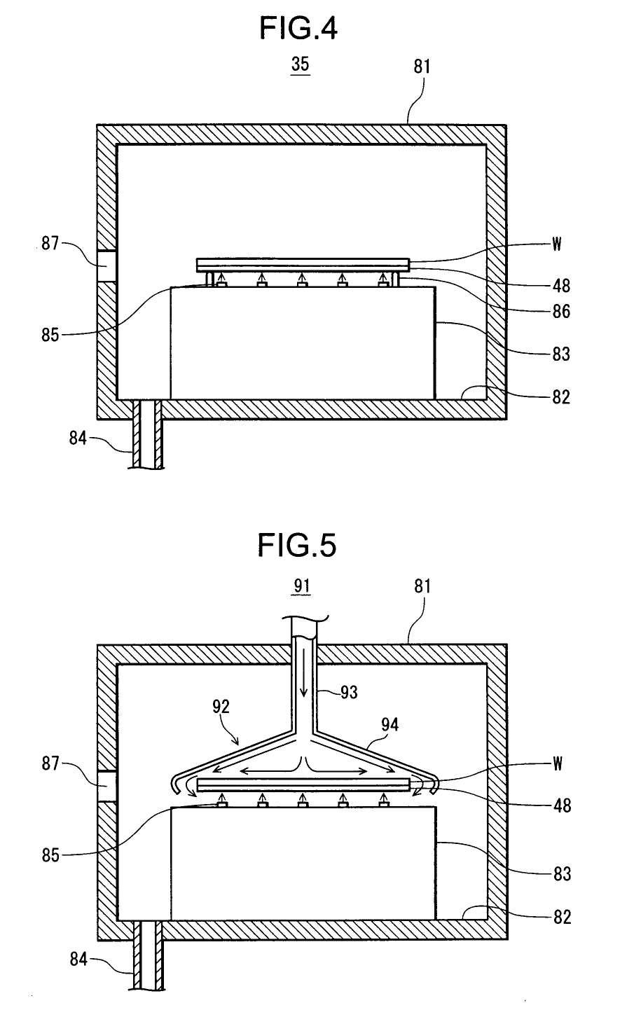

FIG. 4 is sectional view schematically showing the construction of the cleaning module 35 appearing in FIG. 1.

As shown in FIG. 4, the cleaning module 35 has a chamber 81 as a box-shaped container housing a wafer W having a rear surface on which the protective film 48 described above has been printed and a front surface which has been subjected to the RIE processing described above, a mounting stage 83 that is disposed in a bottom portion 82 of the chamber 81, and an exhaust pipe 84 that discharges gas and the like in the chamber 81 to the outside.

The mounting stage 83 is a cylindrical projection and has therein a normal pressure plasma producing unit (not shown) that turns a processing gas supplied at normal pressure into plasma to produce ions and radicals, and has an upper surface in which are formed a plurality of jet holes 85 from which the ions and radicals produced by the normal pressure plasma producing unit are jetted. A plurality of lift pins 86 are disposed on an upper surface of the mounting stage 83. The top of each lift pin 86 is conical, and the lift pins 86 contact the protective film 48 printed on a rear surface of a wafer W transferred into the chamber 81 and support the wafer W. The lift pins 86 can move the wafer W vertically as viewed in the drawing. To remove the protective film 48 printed on the rear surface of the wafer W, the lift pins 86 move the wafer W so that the gap between the protective film 48 printed on the rear surface of the wafer W and each jet hole 85 can be 1 to 3 mm, and when the wafer W is to be transferred into and out from the chamber 81, the lift pins 86 move the wafer W so that the wafer W can be positioned at the height of a transfer port 87 for the wafers W, which is provided in a side wall of the chamber 81.

In the cleaning module 35, ions and the like are jetted from the jet holes 85 toward the protective film 48 printed on the rear surface of the wafer W supported by the lift pins 86. The ions and the like jetted from the jet holes 85 decompose and remove the protective film 48 (normal pressure plasma ashing process). It should be noted that areas of contact of the protective film 48 with the lift pins 86 cannot be decomposed and removed because contact of the ions and the like is obstructed by the lift pins 86. Therefore, the transfer arm mechanism 32 shifts the position of the wafer W to bring the wafer W into contact with the lift pins 86 again, so that the protective film in the areas of contact is decomposed and removed in the same manner.

Although in the present embodiment, the mounting stage 83 has therein the normal pressure plasma producing unit, and ions and the like produced by the normal pressure plasma producing unit are jetted from the plurality of jet holes 85 so that the protective film 48 can be decomposed and removed by the ions and the like, this is not limitative, but rather the mounting stage 83 may have a superheated steam producing unit that produces superheated steam in the mounting stage 83, and the superheated steam produced by the superheated steam producing unit may be jetted from the plurality of jet holes 85 so that the protective film 48 can be removed by the superheated steam (superheated steam jetting process). Here, superheated steam with a temperature of not less than 120° C. is used.

Moreover, in the present embodiment, at least one suction port for sucking ions and the like and superheated steam and the like jetted from the jet holes 85 may be provided in the upper surface of the mounting stage 83.

Referring again to FIG. 1, the substrate processing system 10 has a system controller (not shown) that controls operation of the component elements, for example, the transfer module 11, the process modules 12 to 15, and the loader module 16, and an operation panel 90 disposed at one end of the loader module 16 as viewed in the longitudinal direction thereof.

The operation panel 90 has a display unit comprised of, for example, an LCD (liquid crystal display), and the display unit displays operating states of the component elements of the substrate processing system 10.

According to the substrate processing system 10 described above, the protective film 48 with a thickness of 30 to 50 μm is printed on the rear surface of the wafer W before the wafer W is subjected to the RIE processing, and the protective film 48 is removed from the rear surface of the wafer W by the normal pressure plasma ashing process after the wafer W has been subjected to the RIE processing, and hence the protective film 48 can be thickly printed on the rear surface of the wafer W, and also the protective film 48 can be reliably removed. Moreover, in the process module 13, the susceptor 52 contacts the thick protective film 48 printed on the rear surface of the wafer W. Thus, even when the wafer W is being repeatedly attracted to and held on the susceptor 52 electrostatically, the rear surface of the wafer W and the upper surface of the susceptor 52 can be reliably prevented from getting scratched, and the degree of adhesion between the wafer W and the susceptor 52 is increased, so that the temperature of the wafer W can be controlled in a more reliably manner. Moreover, the wafer W can be attracted to and held on the upper surface of the susceptor 52 in a state with the base material of the susceptor 52 being exposed without disposing the electrostatic chuck in the upper portion of the susceptor 52, and hence the construction of the susceptor 52 can be simplified.

In the substrate processing system 10, because the printing module 34 prints the protective film 48 by carrying out the screen printing process, the printing module 34 is an atmospheric processing apparatus. Therefore, the protective film 48 can be printed on the rear surface of the wafer W at normal pressure, and hence the throughput of the substrate processing system 10 is not significantly decreased. Moreover, because the loader module 16 is an atmospheric substrate transfer apparatus, the printing module 34 can be easily connected to the loader module 16. Therefore, it is not necessary to make substantial changes to the construction of a conventional substrate processing system for the connecting printing module 34 to the loader module 16.

Moreover, in the substrate processing system 10, because the cleaning module 35 removes the protective film 48 by carrying out the normal pressure plasma ashing process, the cleaning module 35 is an atmospheric processing apparatus. Therefore, the protective film 48 can be removed from the rear surface of the wafer W at normal pressure, and hence the throughput of the substrate processing system 10 is not significantly decreased. Moreover, because the loader module 16 is an atmospheric substrate transfer apparatus, the cleaning module 35 can be easily connected to the loader module 16. Therefore, it is not necessary to make substantial changes to the construction of a conventional substrate processing system for connecting the cleaning module 35 to the loader module 16.

Next, a description will be given of a variation of the above described cleaning module that removes the protective film from the rear surface of the wafer W.

The present variation is basically the same as the cleaning module 35 described above in terms of construction and operation, differing from the cleaning module 35 in the way of holding the wafer W. Features of the construction and operation that are the same as those of the cleaning module 35 will thus not be described, only features that are different from those of the cleaning module 35 being described below.

FIG. 5 is a sectional view schematically showing the construction of the variation of the cleaning module that removes the protective film from the rear surface of the wafer W.

As shown in FIG. 5, the cleaning module 91 has a Bernoulli chuck unit 92 provided above the mounting stage 83. The Bernoulli chuck unit 92 has a gas introducing pipe 93, and a nozzle 94 that is connected to the gas introducing pipe 93, broadens toward the end, and has an outer end thereof bending inward.

As shown in FIG. 5, the Bernoulli chuck unit 92 introduces a predetermined gas from the gas introducing pipe 93 into the nozzle 94, which then supplies the introduced gas toward the wafer W from the front surface side thereof. Then, the gas introduced from the front surface side of the wafer W passes to the rear surface side of the wafer W, and the wafer W is caused to float due to a gas pressure difference produced between the front surface side and the rear surface side of the wafer W, so that the wafer W can be suspended without contacting not only the Bernoulli chuck unit 92 but also the mounting stage 83.

In the cleaning module 91, the normal pressure plasma ashing process or the superheated steam jetting process is carried out on the protective film 48 printed on the rear surface of the wafer W, which is suspended without contacting not only the Bernoulli chuck unit 92 but also the mounting stage 83, so as to remove the protective film 48 from the rear surface of the wafer W.

According to the present variation, because the protective film 48 is removed from the rear surface of the wafer W, which is suspended without contacting not only the Bernoulli chuck unit 92 but also the mounting stage 83, by carrying out the normal pressure plasma ashing process or the superheated steam jetting process, the protective film 48 can be reliably removed from the rear surface of the wafer W. Therefore, it is unnecessary to shift the position of the wafer W and carry out the normal pressure ashing process or the superheated steam jetting process again as in the case of the above described cleaning module 35, and hence a decrease in the throughput of the substrate processing system 10 can be reliably prevented.

Further, the substrates subjected to the etching processing in the substrate processing system according to the present embodiment are not limited to being semiconductor wafers, but rather may instead be any of various substrates used in LCDs (Liquid Crystal Displays), FPDs (Flat Panel Displays) or the like, photomasks, CD substrates, printed substrates, or the like.

It is to be understood that the object of the present invention may also be accomplished by supplying a system or an apparatus with a storage medium in which a program code of software, which realizes the functions of the above described embodiment is stored, and causing a computer (or CPU or MPU) of the system or apparatus to read out and execute the program code stored in the storage medium.

In this case, the program code itself read from the storage medium realizes the functions of the above described embodiment, and hence the program code and a storage medium on which the program code is stored constitute the present invention.

Examples of the storage medium for supplying the program code include a floppy (registered trademark) disk, a hard disk, a magnetic-optical disk, an optical disk such as a CD-ROM, a CD-R, a CD-RW, a DVD-ROM, a DVD-RAM, a DVD-RW, and a DVD+RW, a magnetic tape, a nonvolatile memory card, and a ROM. Alternatively, the program code may be downloaded via a network.

Further, it is to be understood that the functions of the above described embodiment may be accomplished not only by executing a program code read out by a computer, but also by causing an OS (operating system) or the like which operates on the computer to perform a part or all of the actual operations based on instructions of the program code.

Further, it is to be understood that the functions of the above described embodiment may be accomplished by writing a program code read out from the storage medium into a memory provided in an expansion board inserted into a computer or a memory provided in an expansion unit connected to the computer and then causing a CPU or the like provided in the expansion board or the expansion unit to perform a part or all of the actual operations based on instructions of the program code.

What is claimed is:

1. A substrate processing system having an etching apparatus that subjects a substrate to plasma etching processing, a vacuum substrate transfer apparatus having the etching apparatus connected thereto, and an atmospheric substrate transfer apparatus connected to the vacuum substrate transfer apparatus, wherein the etching apparatus has a mounting stage that electrostatically attracts and holds the substrate, and the mounting stage contacts a rear surface of the substrate, the substrate processing system comprising:
a protective film printing apparatus that is connected to the atmospheric substrate transfer apparatus and prints a protective film on the rear surface of the substrate before the substrate is subjected to the plasma etching processing; and
a protective film removing apparatus that is connected to the atmospheric substrate transfer apparatus and removes the protective film from the rear surface of the substrate after the substrate has been subjected to the plasma etching processing.

2. A substrate processing system as claimed in claim 1, wherein said protective film printing apparatus prints the protective film by carrying out a screen printing process.

3. A substrate processing system as claimed in claim 1, wherein said protective film printing apparatus prints the protective film by attaching a predetermined film.

4. A substrate processing system as claimed in claim 1, wherein said protective film removing apparatus removes the protective film by carrying out a normal pressure plasma ashing process.

5. A substrate processing system as claimed in claim 1, wherein said protective film removing apparatus removes the protective film by carrying out a superheated steam jetting process.

6. A substrate processing system as claimed in claim 1, wherein the protective film is made of resin.

7. A substrate processing system as claimed in claim 1, wherein the protective film is made of one selected from the following: silica, organic polymer of fluorine-free aromatic hydrocarbon, polyimide, and resist.

8. A substrate processing system as claimed in claim 1, wherein in an upper portion of the mounting stage, a base material of the mounting stage is exposed.

9. A substrate processing system as claimed in claim 1, wherein said protective film removing apparatus holds the substrate without contacting the substrate.

10. A substrate processing method in a substrate processing system having at least an etching apparatus that subjects a substrate to plasma etching processing, wherein the etching apparatus has a mounting stage that electrostatically attracts and holds the substrate, and the mounting stage contacts a rear surface of the substrate, the substrate processing method comprising:
a printing step of printing a protective film on the rear surface of the substrate;
an etching step of subjecting a front surface of the substrate to the plasma etching processing; and
a removing step of removing the protective film.

11. A substrate processing method as claimed in claim 10, wherein in said printing step, the protective film is printed by carrying out a screen printing process.

12. A substrate processing method as claimed in claim 10, wherein in said printing step, the protective film is printed by attaching a predetermined film.

13. A substrate processing method as claimed in claim 10, wherein in said removing step, the protective film is removed by carrying out a normal pressure plasma ashing process.

14. A substrate processing method as claimed in claim 10, wherein in said removing step, the protective film is removed by carrying out a superheated steam jetting process.

15. A substrate processing method as claimed in claim 10, wherein the protective film is made of resin.

16. A substrate processing method as claimed in claim 10, wherein the protective film is made of one selected from the following: silica, organic polymer of fluorine-free aromatic hydrocarbon, polyimide, and resist.

17. A substrate processing method as claimed in claim 10, wherein in said removing step, the substrate is held without contact.

18. A computer-readable storage medium storing a program for causing a computer to execute a substrate processing method in a substrate processing system having at least an etching apparatus that subjects a substrate to plasma etching processing, wherein the etching apparatus has a mounting stage that electrostatically attracts and holds the substrate, and the mounting stage contacts a rear surface of the substrate, the substrate processing method comprising:
a printing step of printing a protective film on the rear surface of the substrate;
an etching step of subjecting a front surface of the substrate to the plasma etching processing; and
a removing step of removing the protective film.
